(19) United States
(12) Patent Application Publication
(10) Pub. No.: US 2010/0301437 A1
(43) Pub. Date: Dec. 2, 2010

(54) Anti-Reflective Coating For Sensors Suitable For High Throughput Inspection Systems

(75) Inventor: David L. Brown, Sunnyvale, CA (US)

Correspondence Address: BEVER, HOFFMAN & HARMS, LLP, 901 CAMPISI WAY, SUITE 370, CAMPBELL, CA, 95008, US

(73) Assignee: KLA-Tencor Corporation, San Jose, CA (US)

(21) Appl. No.: 12/476,190

(22) Filed: Jun. 1, 2009

(51) Int. Cl. H01L 31/0216

(52) U.S. Cl. 257/432; 438/72; 257/E31.12

(57) ABSTRACT

A sensor for capturing light at the ultraviolet (UV) or the deep UV wavelength includes a multi-layer anti-reflective coating (ARC). In a two-layer ARC, the first layer is formed on either the substrate or the circuitry layer, and the second layer is formed on the first layer and receives the light as an incident light beam. Notably, the first layer is at least twice as thick as the second layer, thereby minimizing an electrical field at a substrate surface due to charge trapping in the ARC. In a four-layer ARC, the third layer is formed on the second layer and the fourth layer is formed on the third layer. The first and third layers may be formed from the same material, and the second and fourth layers may be formed from materials having same/similar indexes of refraction. In this case, the first layer is at least twice as thick as any of the second, third, or fourth layers.

### BACKGROUND OF THE INVENTION

1. Field of the Invention

The present invention relates to an anti-reflective coating (ARC), and in particular to an ARC for sensors in high throughput inspection systems.

2. Related Art

Image sensors are ubiquitous in the field of integrated circuit (IC) inspection. Among other requirements, a sensor is designed to capture light reflected from an IC surface, thereby allowing defect detection and IC layer measurements. The quantum efficiency (QE) of the sensor measures the percentage of the light that is actually captured by the sensor. Thus, a QE of 100% means that all incident light on the sensor is captured. To reduce reflections, which would degrade the effective QE of the sensor, one or more coatings can be used on the surface of the sensor.

For example, U.S. Pat. No. 4,822,748, which issued to Janesick et al. on Apr. 18, 1989, describes overthinning a backside of a charge-coupled device (CCD) image sensor and then growing a high quality oxide film on the surface of the sensor, thereby leaving a depletion region just under the oxide film. At this point, the backside of the thinned photosensitive material can be flooded with intense ultraviolet radiation, thereby producing an accumulation layer of holes. According to Janesick, this technique significantly increases the QE of the CCD image sensor. This QE increase illustrates that the thin film coating influences the surface reflectivity of the sensor and impacts the sensor surface condition as well as associated electronic properties such as QE, wherein these electrical properties can change dynamically under UV illumination.

U.S. Application 2007/0012962, published on Jan. 18, 2007 and filed by Rhodes on Jul. 18, 2005, describes a multi-layer coating used for a surface of a light sensitive element in a substrate. Specifically, Rhodes teaches forming an anti-reflective coating (ARC) to cover a photodiode in the substrate. Exemplary ARCs include silicon nitride (Si₃N₄), silicon oxy-nitride (SiOₓN_{y}), or combinations SiO₂/Si₃N₄, SiOₓN_{y}/Si₃N₄, SiOₓN_{y}/Si₃N₄/SiO_{w}N_{z}, SiOₓN_{y}/Si₃O_{c}N₂/SiO_{q}Nᵤ). An underlying oxide layer (e.g. RTO or furnace oxide or insulator) acts as a stop layer when the ARC is patterned and etched as well as minimizing stress between the ARC and the silicon substrate. Rhodes teaches that the thickness of the ARC should be chosen to eliminate reflections near the incident wavelengths that are being detected. For example, for the visible spectrum, Rhodes teaches thicknesses for the ARC to be between 200-1000 angstroms. Rhodes etches a spacer insulator layer deposited over the ARC to form sidewalls of the transistor control gates and the ARC. According to Rhodes, this configuration can eliminate a “hedge” at the shallow trench isolation between the p-well and the n-well.

U.S. Application 2005/0110050, published on May 26, 2005 and filed by Walschap et el. on Nov. 20, 2003, describes an image sensor device having both a planarization layer and an ARC. The planarization layers can be a polymer, e.g. a photoresist, polyimide, spin-on glass, benzocyclobutene, a type of cross-linked polymers, or a set of sublayers. Walschap determines the thickness of the planarization layer based only on the surface roughness of the pixel structure from the image sensor device. In contrast, Walschap determines the thickness of the ARC such that an optical path difference equals a number of half wavelengths of the light the ARC is designed for, so that destructive interference occurs between the light reflected at the top of the ARC layer and the light reflected at the ARC/device interface.

As indicated by the above references, the deposition and the optimizing of the ARCs are optimized for specific wavelengths. Notably, most ARCs are applied to surfaces that are not impacted by the detailed chemistry and charge trapping in the coating. That is, ARCs can be damaged by ultraviolet (UV) light and form charge traps therein. These traps change the surface electrostatic conditions at the interface and undesirably reduce the efficiency of the sensor.

While significant interest in producing stable surfaces under UV and DUV illumination has existed for decades, much has been motivated by astronomical applications. These applications generally have low illumination levels, require long exposure times typically from seconds to hours, and result in relatively low total exposures of UV light onto the sensor. For the present application of high-speed inspection, the readout times are much shorter, typically less than one millisecond, and the corresponding total exposures over the sensor lifetime can be many orders of magnitude larger. The stability requirements become much more severe under these extreme conditions.

Therefore, a need arises for one or more materials that can be applied directly to the surface of the sensor without affecting its performance.

### SUMMARY OF THE INVENTION

A sensor for capturing light at the ultraviolet (UV) or the deep UV wavelength is described. This sensor includes a substrate, a circuitry layer formed on the substrate for detecting the light, and a multi-layer anti-reflective coating (ARC) formed on the substrate (for a back-illuminated sensor) or the circuitry layer (for a front-illuminated sensor). In one embodiment of a two-layer ARC, the first layer can be formed on the substrate (or circuitry layer), and the second layer can be formed on the first layer and can receive the light as an incident light beam. Notably, the first layer is at least twice as thick as the second layer, thereby minimizing an electrical field at a substrate surface due to charge trapping in the ARC. To minimize reflections of the light, the first and second layers have different indexes of refraction.

In one embodiment, the first layer can be silicon dioxide having a thickness range of 113-123 nm (e.g. approximately 118 nm thick), and the second layer can be silicon nitride having a thickness range of 36-46 nm (e.g. approximately 41 nm thick). In another embodiment, the first layer can be silicon dioxide having a thickness range of 111-121 nm thick (e.g. approximately 116 nm thick), and the second layer can be hafnium oxide having a thickness range of 39-49 nm thick (e.g. approximately 44 nm thick). In yet another embodiment, the first layer can be silicon dioxide having a thickness range of 231-241 nm thick (e.g. approximately 236 nm thick), and the second layer can be silicon nitride having a thickness range of 37-47 nm thick (e.g. 42 nm thick).

The sensor can include an ARC including more than 2 layers. For example, an ARC having 4 layers is also described. In this embodiment, the third layer can be formed on the second layer and the fourth layer can be formed on the third layer. In this case, the second, third, and fourth layers receive the light as an incident light beam. The first layer is at least twice as thick as any of the second layer, the third layer, and the fourth layer. The first and third layers may have the same indexes of refraction and the second and fourth layers may have the same/similar indexes of refraction for simplicity of fabrication, but the first and second layers typically should have different indexes of refraction in order to provide an effective coating design. The first, second, third, and fourth layer combined effects reduce reflections of the incident light.

In one embodiment of the 4-layer ARC, the first layer can be silicon dioxide having a thickness range of 110-120 nm (e.g. approximately 115 nm thick), the second layer can be silicon nitride having a thickness range of 48-58 nm (e.g. approximately 53 nm thick), the third layer can be silicon dioxide having a thickness range of 44-54 nm (e.g. approximately 49 nm thick), and the fourth layer can be silicon nitride having a thickness range of 27-37 nm (e.g. approximately 32 nm thick).

In another embodiment of the 4-layer ARC, the first layer can be silicon dioxide having a thickness range of 75-85 nm (e.g. approximately 80 nm thick), the second layer can be silicon nitride having a thickness range of 25-35 nm (e.g. approximately 30 nm thick), the third layer can be silicon dioxide having a thickness range of 39-49 nm (e.g. approximately 44 nm thick), and the fourth layer can be silicon nitride having a thickness range of 24-34 nm (e.g. approximately 29 nm thick).

In yet another embodiment of the 4-layer ARC, the first layer can be silicon dioxide having a thickness range of 111-121 nm (e.g. approximately 116 nm thick), the second layer can be hafnium oxide having a thickness range of 42-52 nm (e.g. approximately 47 nm thick), the third layer can be silicon dioxide having a thickness range of 44-54 nm (e.g. approximately 49 nm thick), and the fourth layer can be hafnium oxide having a thickness range of 45-55 nm (e.g. approximately 50 nm thick).

In yet another embodiment of the 4-layer ARC, the first layer can be silicon dioxide having a thickness range of 76-86 nm (e.g. approximately 81 nm thick), the second layer can be hafnium oxide having a thickness range of 27-37 nm (e.g. approximately 32 nm thick), the third layer can be silicon dioxide having a thickness range of 39-49 nm (e.g. approximately 44 nm thick), and the fourth layer can be hafnium oxide having a thickness range of 27-37 nm (e.g. approximately 32 nm thick).

In yet another embodiment of the 4-layer ARC, the first layer can be silicon dioxide having a thickness range of 111-121 nm (e.g. approximately 116 nm thick), the second layer can be hafnium oxide having a thickness range of 42-52 nm (e.g. approximately 47 nm thick), the third layer can be silicon dioxide having a thickness range of 44-54 nm (e.g. approximately 49 nm thick), and the fourth layer can be silicon nitride having a thickness range of 43.5-53.5 nm (e.g. approximately 48.5 nm thick).

In yet another embodiment of the 4-layer ARC, the first layer can be silicon dioxide having a thickness range of 231-341 nm (e.g. approximately 236 nm thick), the second layer can be hafnium oxide having a thickness range of 42-52 nm (e.g. approximately 47 nm thick), the third layer can be silicon dioxide having a thickness range of 44-54 nm (e.g. approximately 49 nm thick), and the fourth layer can be silicon nitride having a thickness range of 43.5-53.5 nm (e.g. approximately 48.5 nm thick).

In yet another embodiment of the 4-layer ARC, the first layer can be silicon dioxide having a thickness range of 164-174 nm (e.g. approximately 169 nm thick), the second layer can be hafnium oxide having a thickness range of 27-37 nm (e.g. approximately 32 nm thick), the third layer can be silicon dioxide having a thickness range of 39-49 nm (e.g. approximately 44 nm thick), and the fourth layer can be hafnium oxide having a thickness range of 27-37 nm (e.g. approximately 32 nm thick).

### BRIEF DESCRIPTION OF THE DRAWINGS

FIG. 1 illustrates an exemplary sensor.

FIGS. 2A and 2B illustrate exemplary multi-layer anti-reflective coatings formed on a substrate.

FIGS. 3A-3J illustrate graphs that plot intensity reflection versus wavelength for exemplary multi-layer ARC sensors.

### DETAILED DESCRIPTION OF THE DRAWINGS

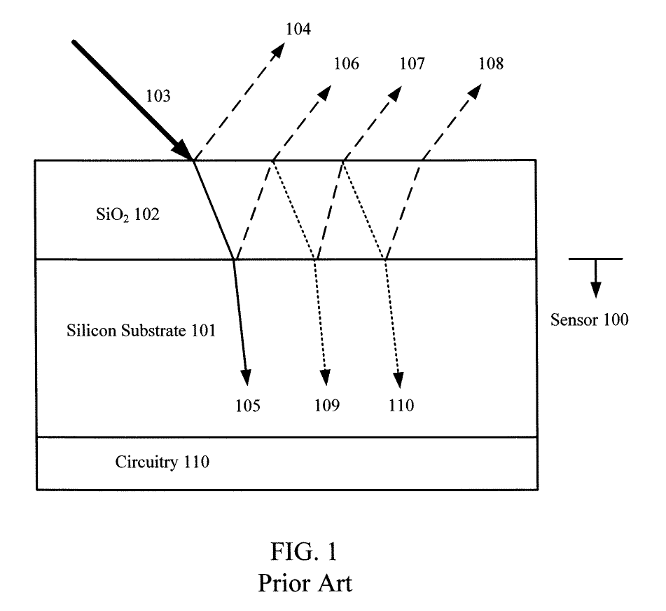

Anti-reflective coatings (ARCs) are thin dielectric films deposited on a surface to reduce specular reflections. FIG. 1 illustrates an exemplary sensor 100 that includes a circuitry layer 110 formed on a silicon substrate 101. Because silicon reacts with air, a silicon dioxide (SiO₂) layer 102 (e.g. a native oxide layer) forms on silicon substrate 101. In operation with near UV and UV illumination, light penetrates into the silicon substrate 101 (and thus also, silicon dioxide layer 102), but does not reach circuitry layer 110. The circuitry layer 110 collects the electrons that are generated by the light penetrating silicon substrate 101.

As an incident light beam 103 (e.g. light reflected from an integrated circuit being tested) is refracted by the boundaries of silicon dioxide layer 102 and silicon substrate 101, as shown by beam 105. In addition to refraction, some part of incident beam 103 and beam 105 is also reflected by these boundaries, as shown by beams 104 and 106. Beam 106 is in turn reflected and refracted at the material boundaries, as shown by beams 109 and 107. Beam 107 is in turn reflected and refracted at the material boundaries, as shown by beams 110 and 108. Note that the refraction/reflection angles and layer thicknesses shown in FIG. 1A are not to scale, but are merely used to demonstrate that a single incident light beam can be refracted and reflected multiple times at the boundaries of silicon substrate 101 and silicon dioxide layer 102. Thus, other refractions and reflections can occur based on beam 108, for example, but are not shown for simplicity.

optimally, the sum of the beams coming out of sensor 100 (e.g. beams 104, 106, 107, and 108) are equal in amplitude to the secondary beams in sensor 100 (e.g. beams 109 and 110), but opposite in phase. When outgoing beams are effectively cancelled by the ingoing secondary beams, circuit layer 110 can receive the maximum light from incident beam 103 (via beam 105).

Silicon substrate 101 has a high index of refraction, which results in a high surface reflectivity (˜50%). In the absence of SiO₂ layer 102, the corresponding light level for illuminating the IC would have to be increased because 50% of the light is being lost. However, increasing the light levels at the UV or DUV wavelengths can add significant expense to already expensive devices. Fortunately, SiO₂ layer 102 has a lower index of refraction. Therefore, by using an appropriate thickness of SiO₂ layer 102, a net outgoing reflection from sensor 100 can be minimized. However, a single layer of SiO₂ is not sufficient to produce a high performance ARC in the UV wavelength range.

Unfortunately, both UV and DUV light can be actinic, i.e. change the surface material it hits. Specifically, the energy of the photons in UV/DUV light is high enough to break bonds in the material and to excite charged particles into trap states. This effect allows charging areas to be created in SiO₂ layer 102, which in turn creates an electric field near the surface of silicon substrate 101. This electric field can pull electrons to the surface and prevent them from being collected to detect light. A state of the art sensor uses careful engineering of the electric field near the silicon surface to optimize device quantum efficiency (QE) in the UV spectrum. Therefore, these charging areas can adversely affect the performance of the sensor.

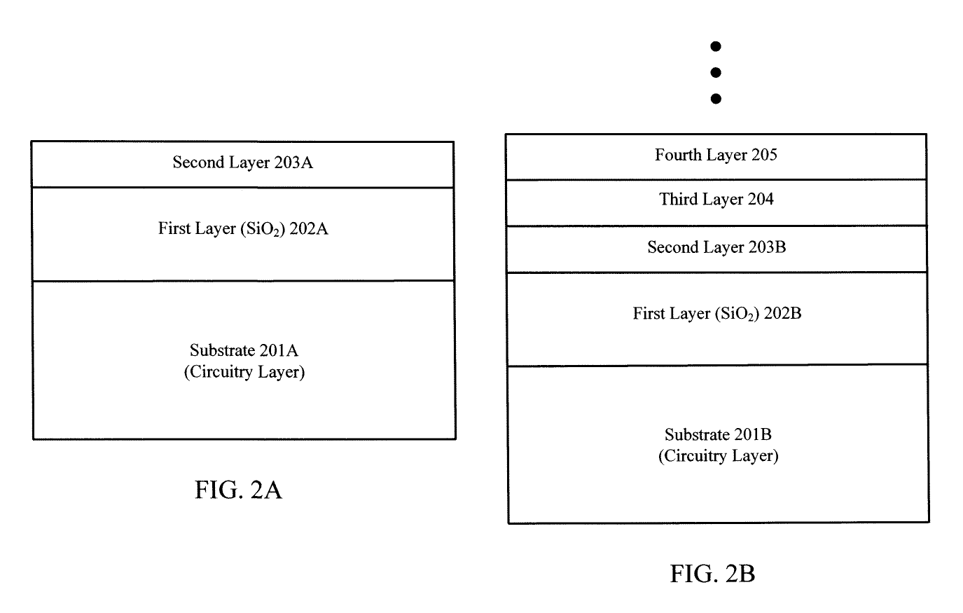

In accordance with one aspect of the invention, a multi-layer coating can be used to minimize the electrical field at the substrate surface due to charge trapping and maximize sensor longevity. FIG. 2A illustrates an exemplary two-layer anti-reflective coating. Specifically, an anti-reflective coating (ARC), which includes a first layer 202A and a second layer 203A, can be formed on a substrate 201A of a sensor. This configuration (i.e. circuitry layer-substrate-ARC) can be used for a back-illuminated sensor. Note that in other embodiments, the ARC can be formed on a circuitry layer (i.e. ARC-circuitry layer-substrate) and used in a front-illuminated sensor.

Front-illuminated sensors are common in the industry and are considered “standard” for sensors. In a front-illuminated sensor, the light passes through or around the wires and devices of the circuitry layer before entering the substrate. For a back-illuminated sensor, the light first enters the substrate (which is typically thinned to a very thin membrane thickness) and for short wavelength visible and for UV wavelengths, does not reach the circuitry layer. For example, FIG. 1 illustrates a back-illuminated sensor 100, wherein the light enters silicon substrate 101, but does not penetrate circuitry layer 110. Thus, a back-illuminated UV sensor can advantageously minimize adverse impact on circuitry layer 110. Note that the surface of a back-illuminated sensor is smoother and more uniform than a surface of a front-illuminated sensor. Therefore, in general, the ARC of a back-illuminated sensor can perform better and have less scattering of light than a front-illuminated sensor.

In one embodiment, first layer 202A is a silicon dioxide (SiO₂) of high quality, e.g. native oxide or a deposited silicon dioxide using well-known production methods in the semiconductor and optics coating industry. Such methods are used, for example, to construct gate oxides for advanced electronic devices. The thickness of first layer 202A can provide a safe distance between less robust materials and the delicate surface of silicon substrate 201A, thereby providing substrate protection for a back-illuminated sensor. Moreover, for either sensor embodiment, this distance can significantly minimize an electrical field at a substrate surface due to charge trapping in the ARC. In a back-illuminated sensor embodiment, this substrate surface is the interface between substrate 201A and first layer 202A. In a front-illuminated sensor embodiment, this substrate surface in the interface between the substrate and the circuitry layer.

Notably, first layer 202A is made thicker than otherwise considered optimum for the optical design. For example, an optical design based on substrate protection and minimization of electrical field may indicate an optimal thickness for first layer 202A to be 50 nanometers (nm). However, because of an addition layer, i.e. a second layer 203, first layer 202A is actually made significantly thicker, e.g. over 100 nm. Thus, the thickness of first layer 202A is actually considered sub-optimal from a purely optical design perspective.

Exemplary materials for second layer 203A include, for example, silicon nitride, hafnium oxide, and magnesium fluoride. Notably, a high-quality silicon dioxide coating for first layer 202A can exhibit much lower trapped charge effects than, for example, a silicon nitride coating. Because second layer 203A exhibits a higher trapped charge propensity than first layer 202A, an electrical field at the substrate surface can be further minimized (i.e. in combination with the extra-thick first layer 202A). Thus, second layer 203A, formed on a thick, low-trapped-charge layer 202A, can advantageously increase the lifetime of the sensor under high exposures compared to known sensors with one or more conventional anti-reflective coatings. Longer lifetime means less scheduled maintenance and lower operating costs over the product lifetime. Additionally, an improved initial sensitivity to expensive UV and deep UV (DUV) light reduces the cost of the illumination system (e.g. a laser system) and/or makes the inspection system potentially faster.

Note that the estimation of the normal incidence reflectivity of an uncoated polished surface can be represented by the equation:

R=((N0−Ns)/(N0+Ns))²

where N0 is the material index of refraction for the incident illumination (typically air) and Ns is the substrate material index at a given wavelength. For silicon, the refractive index at 400 nm wavelength light is ˜5.6 and for air the index is ˜1.0, so the reflectivity is nearly 50%. An ideal single layer ARC 102 should have a refractive index such that

N1²=N0*Ns

where N1 is the ARC layer. A single layer of SiO₂ with an index of ˜1.5 can reduce the reflectivity at UV wavelengths, but cannot eliminate it because the refractive index is far from meeting this condition. Optimizing the ARC performance requires more layers and/or materials.

With respect to the exemplary materials for first layer 202A and second layer 203A, silicon nitride has a higher index of refraction than silicon dioxide. Silicon nitride has refractive index of ˜2.1 which is better suited to optical matching of silicon. However, silicon nitride can trap charge easily and may adversely affect the silicon surface condition when deposited directly on the silicon surface and exposed to UV or DUV light. These damaging effects can be mitigated by interposing a layer of silicon dioxide between the substrate and the silicon nitride layer.

In one embodiment, the thicknesses of first layer 202A and second layer 203A can be “tuned” after materials for those layers and the illumination wavelength are determined. That is, once the materials are designated, then only a limited number of thicknesses can be used for the layers. This tuning can provide the best optical performance for a multi-layer anti-reflective (ARC) coating sensor.

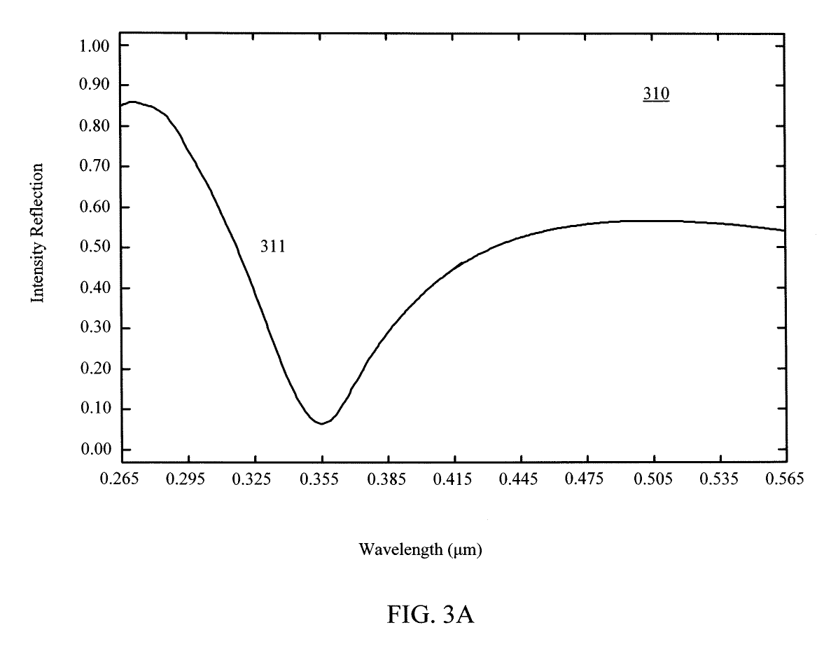

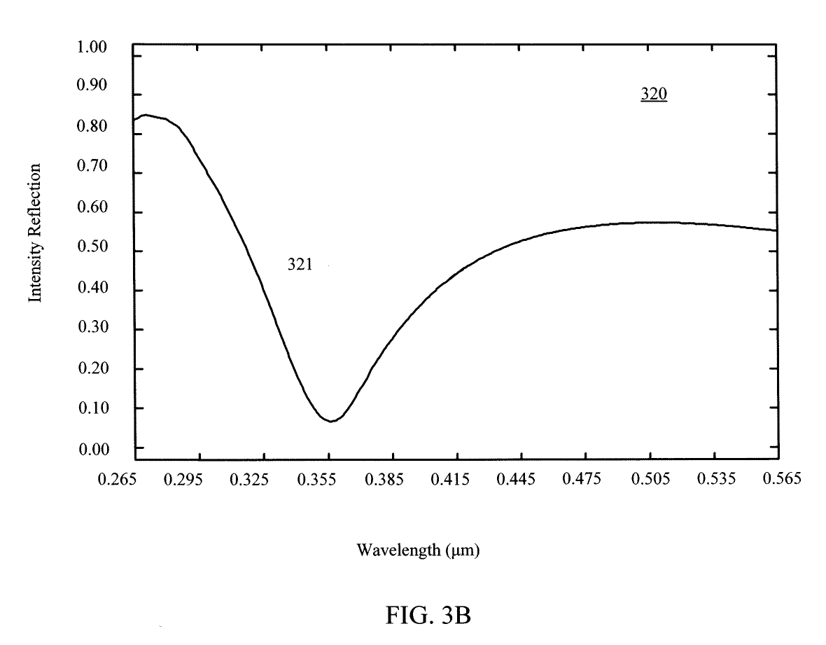

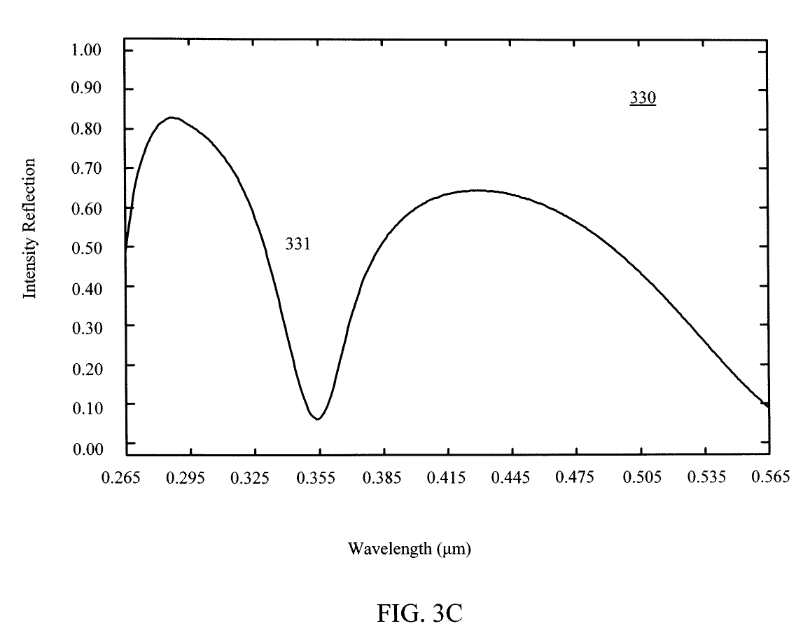

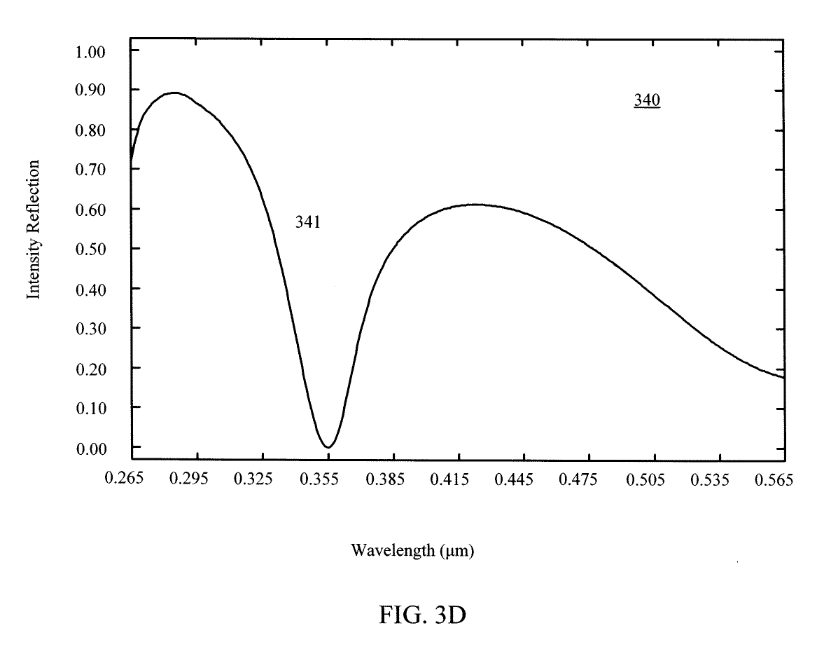

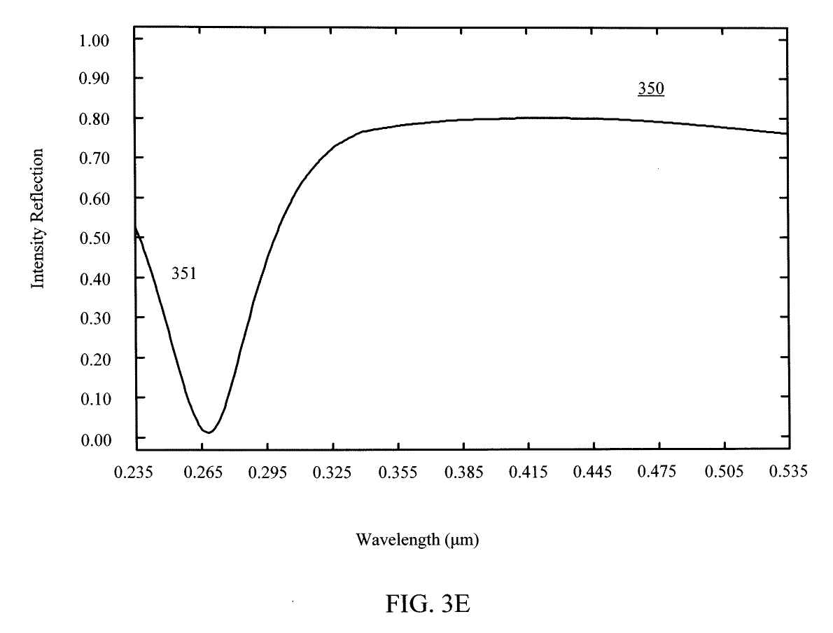

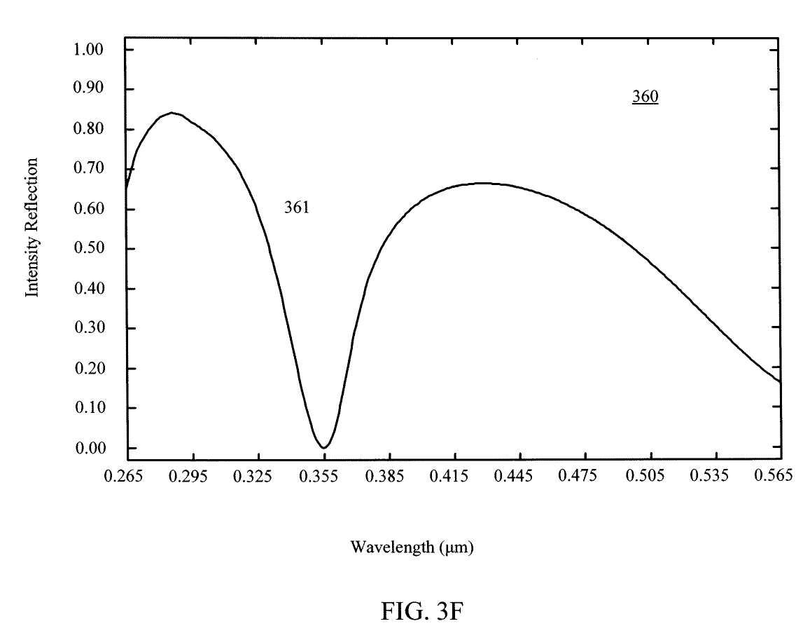

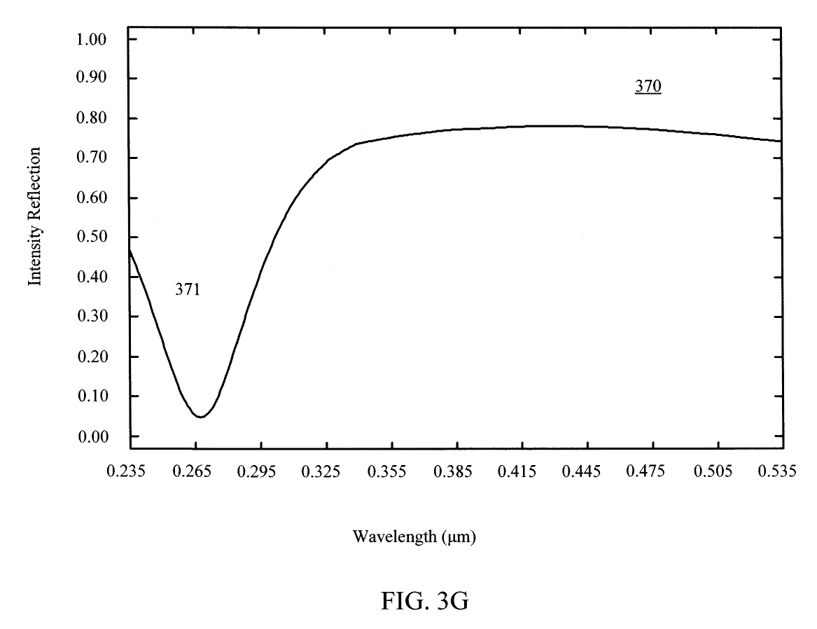

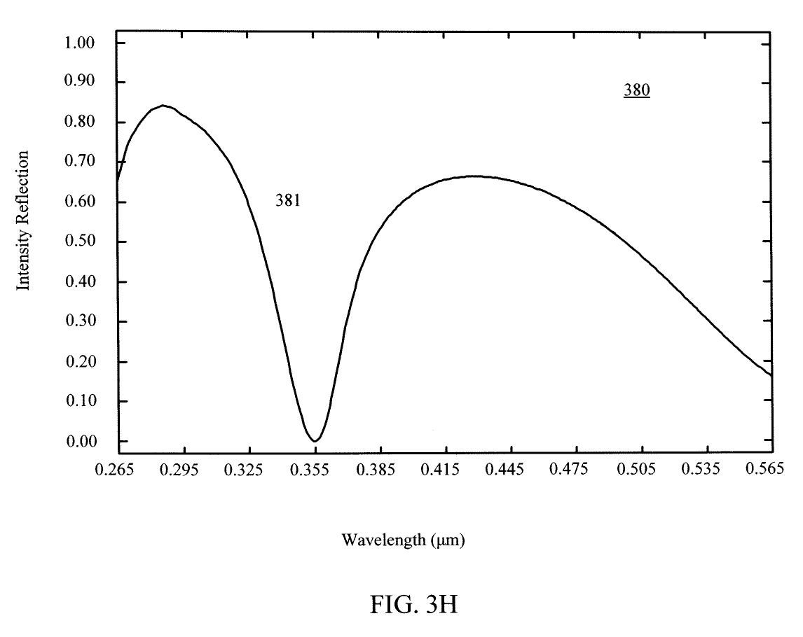

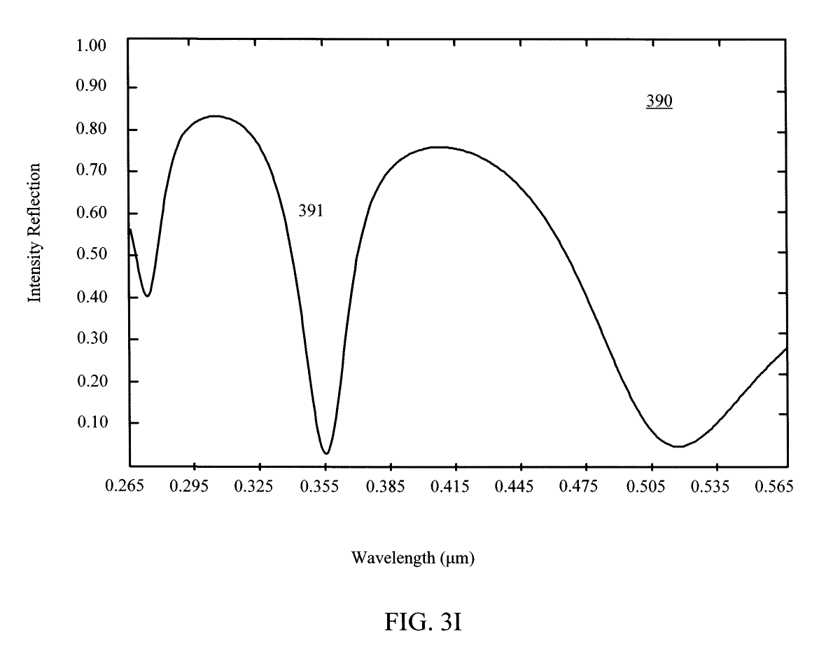

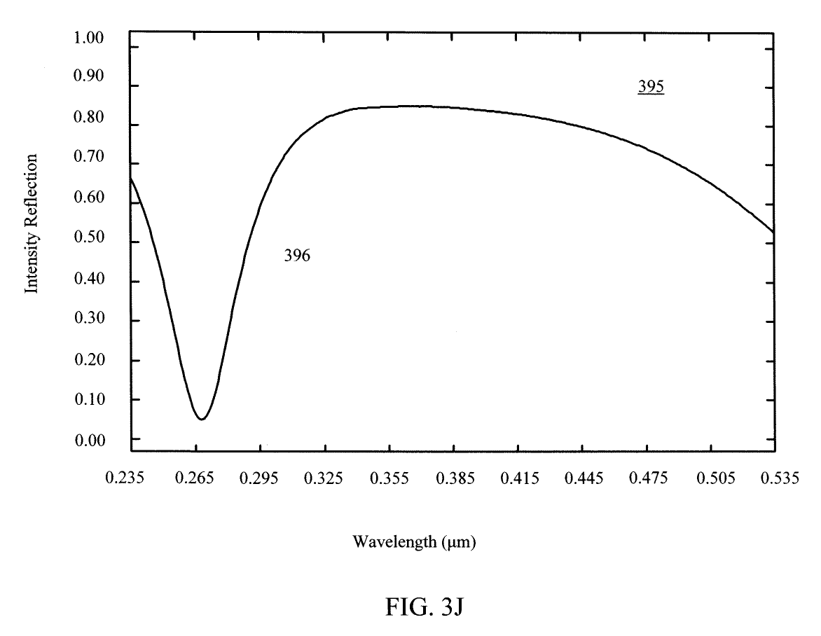

FIG. 3A illustrates a graph 310 that plots intensity reflection (wherein “1” indicates 100% reflection and “0” indicates 0% reflection) versus wavelength for an exemplary multi-layer (2-layer) ARC sensor having a 118 nm layer of silicon dioxide (corresponding to first layer 202A) and a 41 nm layer of silicon nitride (corresponding to second layer 203A). As shown by waveform 311, this exemplary sensor is optimized for a wavelength of 355 nm, as indicated by the intensity reflection being below 0.10 (10%). In other ARC embodiments, first layer 202A could have a silicon dioxide thickness between 113-123 nm and second layer 203A could have a silicon nitride thickness between 36-46 nm.

FIG. 3B illustrates a graph 320 that plots intensity reflection versus wavelength for an exemplary multi-layer ARC sensor having a 116 nm layer of silicon dioxide (corresponding to first layer 202A) and a 44 nm layer of hafnium oxide (corresponding to second layer 203A). As shown by waveform 321, this exemplary sensor is also optimized for a wavelength of 355 nm. In other ARC embodiments, first layer 202A could have a silicon dioxide thickness between 111-121 nm and second layer 203A could have a hafnium oxide thickness between 39-49 nm.

FIG. 3C illustrates a graph 330 that plots intensity reflection versus wavelength for an exemplary multi-layer ARC sensor having a 236 nm layer of silicon dioxide (corresponding to first layer 202A) and a 42 nm layer of silicon nitride (corresponding to second layer 203A). As shown by waveform 331, this exemplary sensor is also optimized for a wavelength of 355 nm. In other ARC embodiments, first layer 202A could have a silicon dioxide thickness between 231-241 nm and second layer 203A could have a silicon nitride thickness between 37-47 nm.

A thicker first layer (e.g. over 200 nm of silicon dioxide) can advantageously provide antireflection properties at multiple illumination wavelengths. For example, the ARC of FIG. 3C can advantageously reduce reflection at three illumination wavelength ranges, i.e. below ˜270 nm, between 325-385 nm, and above ˜500 nm (at visible wavelengths). Note that the narrow width near the 355 nm target wavelength (compared to the less-narrow width near the same target wavelength in FIG. 3B) could reduce manufacturing tolerances as well as the useful acceptance angle of illumination in cases where the illumination is not perfectly 0 degree normal incidence.

In accordance with other embodiments of a multi-layer ARC sensor, more than two layers can be used. For example, FIG. 2B illustrates an ARC including at least four layers formed on a silicon substrate 201B, i.e. first layer 202B, second layer 203B, third layer 204B, and fourth layer 205B. In one embodiment, the ARC can include an even number of layers, with every other layer being the same. For example, first layer 202B and third layer 204B can be formed from the same material, e.g. silicon dioxide. Similarly, second layer 203B and fourth layer 205B can be formed from the same material, e.g. silicon nitride or hafnium oxide.

FIG. 3D illustrates a graph 340 that plots intensity reflection versus wavelength for an exemplary multi-layer (4-layer) ARC sensor having an 115 nm layer of silicon dioxide (corresponding to first layer 202B), a 53 nm layer of silicon nitride (corresponding to second layer 203B), a 49 nm layer of silicon dioxide (corresponding to third layer 204), and a 32 nm layer of silicon nitride (corresponding to fourth layer 205). As shown by waveform 341, this exemplary sensor is optimized for a wavelength of 355 nm. In other ARC embodiments, first layer 202B could have a silicon dioxide thickness between 110-120 nm, second layer 203B could have a silicon nitride thickness between 48-58 nm, third layer 204 could have a silicon dioxide thickness between 44-54 nm, and fourth layer 205 could have a silicon nitride thickness between 27-37 nm.

FIG. 3E illustrates a graph 350 that plots intensity reflection versus wavelength for an exemplary multi-layer (4-layer) ARC sensor having an 80 nm layer of silicon dioxide (corresponding to first layer 202B), a 30 nm layer of silicon nitride (corresponding to second layer 203B), a 44 nm layer of silicon dioxide (corresponding to third layer 204), and a 29 nm layer of silicon nitride (corresponding to fourth layer 205). As shown by waveform 351, this exemplary sensor is optimized for a wavelength of 266 nm. Note that a neodymium-doped yttrium aluminium garnet (Nd:YAG) laser can complement this exemplary sensor (i.e. 355 nm is the 3^{rd} harmonic of a 1066 nm Nd:YAG laser, and 266 nm is the 4^{th} harmonic of the fundamental laser frequency). In other ARC embodiments, first layer 202B could have a silicon dioxide thickness between 75-85 nm, second layer 203B could have a silicon nitride thickness between 25-35 nm, third layer 204 could have a silicon dioxide thickness between 39-49 nm, and fourth layer 205 could have a silicon nitride thickness between 24-34 nm.

FIG. 3F illustrates a graph 360 that plots intensity reflection versus wavelength for an exemplary multi-layer (4-layer) ARC sensor having a 116 nm layer of silicon dioxide (corresponding to first layer 202B), a 47 nm layer of hafnium oxide (corresponding to second layer 203B), a 49 nm layer of silicon dioxide (corresponding to third layer 204), and a 50 nm layer of hafnium oxide (corresponding to fourth layer 205). As shown by waveform 361, this exemplary sensor is optimized for a wavelength of 355 nm. In other ARC embodiments, first layer 202B could have a silicon dioxide thickness between 111-121 nm, second layer 203B could have a hafnium oxide thickness between 42-52 nm, third layer 204 could have a silicon dioxide thickness between 44-54 nm, and fourth layer 205 could have a hafnium oxide thickness between 45-55 nm.

FIG. 3G illustrates a graph 370 that plots intensity reflection versus wavelength for an exemplary multi-layer (4-layer) ARC sensor having an 81 nm layer of silicon dioxide (corresponding to first layer 202B), a 32 nm layer of hafnium oxide (corresponding to second layer 203B), a 44 nm layer of silicon dioxide (corresponding to third layer 204), and a 32 nm layer of hafnium oxide (corresponding to fourth layer 205). As shown by waveform 371, this exemplary sensor is optimized for a wavelength of 266 nm. In other ARC embodiments, first layer 202B could have a silicon dioxide thickness between 76-86 nm, second layer 203B could have a hafnium oxide thickness between 27-37 nm, third layer 204 could have a silicon dioxide thickness between 39-49 nm, and fourth layer 205 could have a hafnium oxide thickness between 27-37 nm.

FIG. 3H illustrates a graph 380 that plots intensity reflection versus wavelength for an exemplary multi-layer (4-layer) ARC sensor having a 116 nm layer of silicon dioxide (corresponding to first layer 202B), a 47 nm layer of hafnium oxide (corresponding to second layer 203B), a 49 nm layer of silicon dioxide (corresponding to third layer 204), and a 48.5 nm layer of silicon nitride (corresponding to fourth layer 205). As shown by waveform 381, this exemplary sensor is optimized for a wavelength of 355 nm. In other ARC embodiments, first layer 202B could have a silicon dioxide thickness between 111-121 nm, second layer 203B could have a hafnium oxide thickness between 42-52 nm, third layer 204 could have a silicon dioxide thickness between 44-54 nm, and fourth layer 205 could have a silicon nitride thickness between 43.5-53.5 nm.

FIG. 3I illustrates a graph 390 that plots intensity reflection versus wavelength for an exemplary multi-layer (4-layer) ARC sensor having a 236 nm layer of silicon dioxide (corresponding to first layer 202B), a 47 nm layer of hafnium oxide (corresponding to second layer 203B), a 49 nm layer of silicon dioxide (corresponding to third layer 204), and a 48.5 nm layer of silicon nitride (corresponding to fourth layer 205). As shown by waveform 391, this exemplary sensor is optimized for a wavelength of 355 nm. In other ARC embodiments, first layer 202B could have a silicon dioxide thickness between 231-241 nm, second layer 203B could have a hafnium oxide thickness between 42-52 nm, third layer 204 could have a silicon dioxide thickness between 44-54 nm, and fourth layer 205 could have a silicon nitride thickness between 43.5-53.5 nm.

FIG. 3J illustrates a graph 395 that plots intensity reflection versus wavelength for an exemplary multi-layer (4-layer) ARC sensor having a 169 nm layer of silicon dioxide (corresponding to first layer 202B), a 32 nm layer of hafnium oxide (corresponding to second layer 203B), a 44 nm layer of silicon dioxide (corresponding to third layer 204), and a 32 nm layer of hafnium oxide (corresponding to fourth layer 205). As shown by waveform 396, this exemplary sensor is optimized for a wavelength of 266 nm. In other ARC embodiments, first layer 202B could have a silicon dioxide thickness between 164-174 nm, second layer 203B could have a hafnium oxide thickness between 27-37 nm, third layer 204 could have a silicon dioxide thickness between 39-49 nm, and fourth layer 205 could have a hafnium oxide thickness between 27-37 nm.

Although illustrative embodiments have been described in detail herein with reference to the accompanying figures, it is to be understood that the invention is not limited to those precise embodiments. They are not intended to be exhaustive or to limit the invention to the precise forms disclosed. As such, many modifications and variations will be apparent to practitioners skilled in this art.

For example, although the substrate can be formed using silicon, other materials can also be used. Note that when the multi-layer ARC is used for a front-illuminated sensor, the thicknesses of each ARC layer may be adjusted to account for wires and devices in the circuitry layer.

Further note that although illumination wavelengths such as 266 nm and 355 nm are discussed herein. Other ARC embodiments may be tailored for other wavelengths including, but not limited to 257 nm, 213 nm, 198 nm and 193 nm.

Additionally, note that certain materials may have dramatically different characteristics depending on the illumination wavelength used, which should be taken into consideration for any implementation. For example, silicon nitride is essentially opaque at 193 nm and therefore would not be used to form an ARC tailored for that wavelength.

Yet further note that although silicon dioxide is discussed herein for the first layer (and also for the third layer for a 4-layer ARC), other embodiments may provide a different dielectric material for the first layer (and the third layer for a 4-layer ARC). This dielectric material as well as the layer deposition method can have dramatic effects on the number of trap states and on the degree of charging.

Accordingly, it is intended that the scope of the invention be defined by the following Claims and their equivalents.

1. A sensor for capturing light, the sensor comprising:
a substrate;
a circuitry layer formed on the substrate for detecting the light; and
an anti-reflective coating (ARC) including:
a first layer formed on one of the substrate and the circuitry layer; and
a second layer formed on the first layer and receiving the light as an incident light beam,
wherein the first layer is at least twice as thick as the second layer, thereby minimizing an electrical field at a substrate surface due to charge trapping in the ARC, and
wherein the first and second layers have different indexes of refraction and reduce reflections of the light.

2. The sensor of claim 1, wherein the first layer is silicon dioxide, 113-123 nm thick, and the second layer is silicon nitride, 36-46 nm thick.

3. The sensor of claim 2, wherein the first layer is approximately 118 nm thick, and the second layer is approximately 41 nm thick.

4. The sensor of claim 1, wherein the first layer is silicon dioxide, 111-121 nm thick, and the second layer is hafnium oxide, 39-49 nm thick.

5. The sensor of claim 4, wherein the first layer is approximately 116 nm thick, and the second layer is approximately 44 nm thick.

6. The sensor of claim 1, wherein the first layer is silicon dioxide, 231-241 nm thick, and the second layer is silicon nitride, 37-47 nm thick.

7. The sensor of claim 6, wherein the first layer is approximately 236 nm thick, and the second layer is approximately 42 nm thick.

8. The sensor of claim 1, wherein the sensor is configured to receive one of ultraviolet (UV) and deep ultraviolet (DUV) wavelengths via a back side of the sensor.

9. The sensor of claim 1, wherein the sensor is configured to receive one of ultraviolet (UV) and deep ultraviolet (DUV) wavelengths via a front side of the sensor.

10. The sensor of claim 1, wherein the substrate is a thinned membrane substrate, and wherein the sensor is configured to receive one of ultraviolet (UV) and deep ultraviolet (DUV) wavelengths.

11. A sensor for capturing light, the sensor comprising:
a substrate;
a circuitry layer formed on the substrate for detecting the light; and
an anti-reflective coating (ARC) including:
a first layer formed on one of the substrate and the circuitry layer;
a second layer formed on the first layer;
a third layer formed on the second layer; and
a fourth layer formed on the third layer,
wherein the second, third, and fourth layers receive the light as an incident light beam,
wherein the first layer is at least twice as thick as any of the second layer, the third layer, and the fourth layer, thereby minimizing an electrical field at a substrate surface due to charge trapping in the ARC,
wherein the first and third layers have same indexes of refraction, the second and fourth layers have at least similar indexes of refraction, the first and second layers have different indexes of refraction, and the first, second, third, and fourth layers reduce reflections of the light.

12. The sensor of claim 11, wherein
the first layer is silicon dioxide, 110-120 nm thick,
the second layer is silicon nitride, 48-58 nm thick,
the third layer is silicon dioxide, 44-54 nm thick, and
the fourth layer is silicon nitride, 27-37 nm thick.

13. The sensor of claim 12, wherein
the first layer is approximately 115 nm thick,
the second layer is approximately 53 nm thick,
the third layer is approximately 49 nm thick, and
the fourth layer is approximately 32 nm thick.

14. The sensor of claim 11, wherein
the first layer is silicon dioxide, 75-85 nm thick,
the second layer is silicon nitride, 25-35 nm thick,
the third layer is silicon dioxide, 39-49 nm thick, and
the fourth layer is silicon nitride, 24-34 nm thick.

15. The sensor of claim 14, wherein
the first layer is approximately 80 nm thick,
the second layer is approximately 30 nm thick,
the third layer is approximately 44 nm thick, and
the fourth layer is approximately 29 nm thick.

16. The sensor of claim 11, wherein
the first layer is silicon dioxide, 111-121 nm thick,
the second layer is hafnium oxide, 42-52 nm thick,
the third layer is silicon dioxide, 44-54 nm thick, and
the fourth layer is hafnium oxide, 45-55 nm thick.

17. The sensor of claim 16, wherein
the first layer is approximately 116 nm thick,
the second layer is approximately 47 nm thick,
the third layer is approximately 49 nm thick, and
the fourth layer is approximately 50 nm thick.

18. The sensor of claim 11, wherein
the first layer is silicon dioxide, 76-86 nm thick,
the second layer is hafnium oxide, 27-37 nm thick,
the third layer is silicon dioxide, 39-49 nm thick, and
the fourth layer is hafnium oxide, 27-37 nm thick.

19. The sensor of claim 18, wherein
the first layer is approximately 81 nm thick,
the second layer is approximately 32 nm thick,
the third layer is approximately 44 nm thick, and
the fourth layer is approximately 32 nm thick.

20. The sensor of claim 11, wherein
the first layer is silicon dioxide, 111-121 nm thick,
the second layer is hafnium oxide, 42-52 nm thick,
the third layer is silicon dioxide, 44-54 nm thick, and
the fourth layer is silicon nitride, 43.5-53.5 nm thick.

21. The sensor of claim 20, wherein
the first layer is approximately 116 nm thick,
the second layer is approximately 47 nm thick,
the third layer is approximately 49 nm thick, and
the fourth layer is approximately 48.5 nm thick.

22. The sensor of claim 11, wherein
the first layer is silicon dioxide, 231-341 nm thick,
the second layer is hafnium oxide, 42-52 nm thick,
the third layer is silicon dioxide, 44-54 nm thick, and
the fourth layer is silicon nitride, 43.5-53.5 nm thick.

23. The sensor of claim 22, wherein
the first layer is approximately 236 nm thick,
the second layer is approximately 47 nm thick,
the third layer is approximately 49 nm thick, and
the fourth layer is approximately 48.5 nm thick.

24. The sensor of claim 11, wherein
the first layer is silicon dioxide, 164-174 nm thick,
the second layer is hafnium oxide, 27-37 nm thick,
the third layer is silicon dioxide, 39-49 nm thick, and
the fourth layer is hafnium oxide, 27-37 nm thick.

25. The sensor of claim 24, wherein
the first layer is approximately 169 nm thick,
the second layer is approximately 32 nm thick,
the third layer is approximately 44 nm thick, and
the fourth layer is approximately 32 nm thick.

26. The sensor of claim 11, wherein the sensor is configured to receive one of ultraviolet (UV) and deep ultraviolet (DUV) wavelengths via a back side of the sensor.

27. The sensor of claim 11, wherein the sensor is configured to receive one of ultraviolet (UV) and deep ultraviolet (DUV) wavelengths via a front side of the sensor.

28. The sensor of claim 11, wherein the substrate is a thinned membrane substrate, and wherein the sensor is configured to receive one of ultraviolet (UV) and deep ultraviolet (DUV) wavelengths.

29. A method of forming an anti-reflective coating (ARC) for a sensor, the sensor for capturing light, the method comprising:
forming a first layer on one of a substrate and a circuitry layer of the sensor; and
forming a second layer on the first layer, the second layer receiving the light as an incident light beam,
wherein the first layer is at least twice as thick as the second layer, thereby minimizing an electrical field at a substrate surface due to charge trapping in the ARC, and
wherein the first and second layers have different indexes of refraction and reduce reflections of the light.

30. The method of claim 29, wherein the sensor is configured to receive one of ultraviolet (UV) and deep ultraviolet (DUV) wavelengths via a back side of the sensor.

31. The method of claim 29, wherein the sensor is configured to receive one of ultraviolet (UV) and deep ultraviolet (DUV) wavelengths via a front side of the sensor.

32. The method of claim 29, wherein the substrate is a thinned membrane substrate, and wherein the sensor is configured to receive one of ultraviolet (UV) and deep ultraviolet (DUV) wavelengths.

33. A method of forming an anti-reflective coating (ARC) for a sensor, the sensor for capturing light, the method comprising:
forming a first layer on one of a substrate and a circuitry layer of the sensor;
forming a second layer on the first layer;
forming a third layer on the second layer; and
forming a fourth layer on the third layer,
wherein the first layer is at least twice as thick as any of the second layer, the third layer, and the fourth layer, thereby minimizing an electrical field at a substrate surface due to charge trapping in the ARC,
wherein the first and third layers have same indexes of refraction, the second and fourth layers have at least similar indexes of refraction, the first and second layers have different indexes of refraction, and the first, second, third, and fourth layers reduce reflections of the light.

34. The method of claim 33, wherein the sensor is configured to receive one of ultraviolet (UV) and deep ultraviolet (DUV) wavelengths via a back side of the sensor.

35. The method of claim 33, wherein the sensor is configured to receive one of ultraviolet (UV) and deep ultraviolet (DUV) wavelengths via a front side of the sensor.

36. The method of claim 33, wherein the substrate is a thinned membrane substrate, and wherein the sensor is configured to receive one of ultraviolet (UV) and deep ultraviolet (DUV) wavelengths.
